(19) United States
(12) Patent Application Publication
(10) Pub. No.: US 2014/0070378 A1
(43) Pub. Date: Mar. 13, 2014

(54) METHOD OF FABRICATING A SEMICONDUCTOR DEVICE, SEMICONDUCTOR WAFER, AND APPARATUS FOR FABRICATING A SEMICONDUCTOR DEVICE

(71) Applicant: KABUSHIKI KAISHA TOSHIBA, Tokyo (JP)

(72) Inventor: Daisuke YAMASHITA, Hyogo (JP)

(73) Assignee: Kabushiki Kaisha Toshiba, Tokyo (JP)

(21) Appl. No.: 13/760,808

(22) Filed: Feb. 6, 2013

(30) Foreign Application Priority Data
Sep. 7, 2012 (JP) 2012-197920

(51) Int. Cl. H01L 21/66; H01L 29/36; G05B 19/418

(52) U.S. Cl. CPC H01L 22/10; H01L 29/365; G05B 19/418
USPC 257/655; 438/5; 700/121

(57) ABSTRACT

An aspect of the present embodiment, there is provided a method of fabricating a semiconductor device, including measuring a physical amount related to an impurity concentration of a semiconductor wafer having a first thickness, deciding a second thickness of the semiconductor wafer based on a measurement value of the physical amount, the second thickness being thinner than the first thickness, and reducing the first thickness of the semiconductor wafer to approximately the same thickness as the second thickness.

### CROSS REFERENCE TO RELATED APPLICATION

This application is based upon and claims the benefit of priority from prior Japanese Patent Application No. 2012-197920, filed on Sep. 7, 2012, the entire contents of which are incorporated herein by reference.

### FIELD

Exemplary embodiments described herein generally relate to a method of fabricating a semiconductor device, a semiconductor wafer and apparatus for fabricating a semiconductor device.

### BACKGROUND

Conventionally, a power semiconductor device such as a medium-breakdown-voltage metal-oxide-semiconductor field-effect transistor (MOSFET) has been fabricated from a diffusion wafer. The diffusion wafer is a wafer obtained by diffusing impurities from both surfaces of a lapped wafer and then grinding one of the surfaces.

However, the fabrication cost of the diffusion wafer is high because a long time is required for a diffusion process. In addition, there is constantly a risk of dependence on stable supply.

In this regard, a normal wafer (polished wafer) that is not subjected to the diffusion process is considered to be used instead of the diffusion wafer.

However, when a power semiconductor device is fabricated from a normal wafer, there is a problem that the characteristics of the fabricated semiconductor device are significantly non-uniform.

### BRIEF DESCRIPTION OF THE DRAWINGS

FIG. 1 is a block diagram showing an apparatus for fabricating a semiconductor device according to a first embodiment;

FIG. 2 is a plan view schematically showing the apparatus for fabricating a semiconductor device according to the first embodiment;

FIG. 3 is a flowchart showing a method for fabricating a semiconductor device according to the first embodiment;

FIG. 4 is a block diagram showing an apparatus for fabricating a semiconductor device according to a second embodiment;

FIG. 5 is a flowchart showing a method for fabricating a semiconductor device according to the second embodiment;

FIG. 6 is a diagram schematically showing a recess unit in a first modification of the second embodiment; and

FIG. 7A is a plan view showing a semiconductor wafer which is subjected to recess treatment in the first modification of the second embodiment, and FIGS. 7B to 7E are graphs each showing a distribution of a variable amount in the semiconductor wafer, in which a horizontal axis indicates a position in the semiconductor wafer and the vertical axis indicates the variable amount.

### DETAILED DESCRIPTION

An aspect of the present embodiment, there is provided a method of fabricating a semiconductor device, including measuring a physical amount related to an impurity concentration of a semiconductor wafer having a first thickness, deciding a second thickness of the semiconductor wafer based on a measurement value of the physical amount, the second thickness being thinner than the first thickness, and reducing the first thickness of the semiconductor wafer to approximately the same thickness as the second thickness.

Another aspect of the present embodiment, there is provided a semiconductor wafer, including a first region having a first impurity concentration, a first sheet resistance and a first thickness, and a second region having a second impurity concentration, a second sheet resistance and a second thickness, wherein both the first region and the second region are satisfied with at least one relation of the first impurity concentration being lower than the second impurity concentration and the first thickness being thicker than the second thickness, the first sheet resistance being higher than the second sheet resistance and the first thickness being thicker than the second thickness, the first impurity concentration being lower than the second impurity concentration and the first thickness being thinner than the second thickness, and the first sheet resistance being higher than the second sheet resistance and the first thickness being thinner than the second thickness.

Another aspect of the present embodiment, there is provided an apparatus for fabricating a semiconductor device, including a measurement unit measuring a physical amount related to an impurity concentration of a semiconductor wafer having a first thickness, a decision unit deciding a second thickness of the semiconductor wafer based on a measurement value of the physical amount, the second thickness being thinner than the first thickness; and a control unit controlling the first thickness to approximately the same thickness as the second thickness.

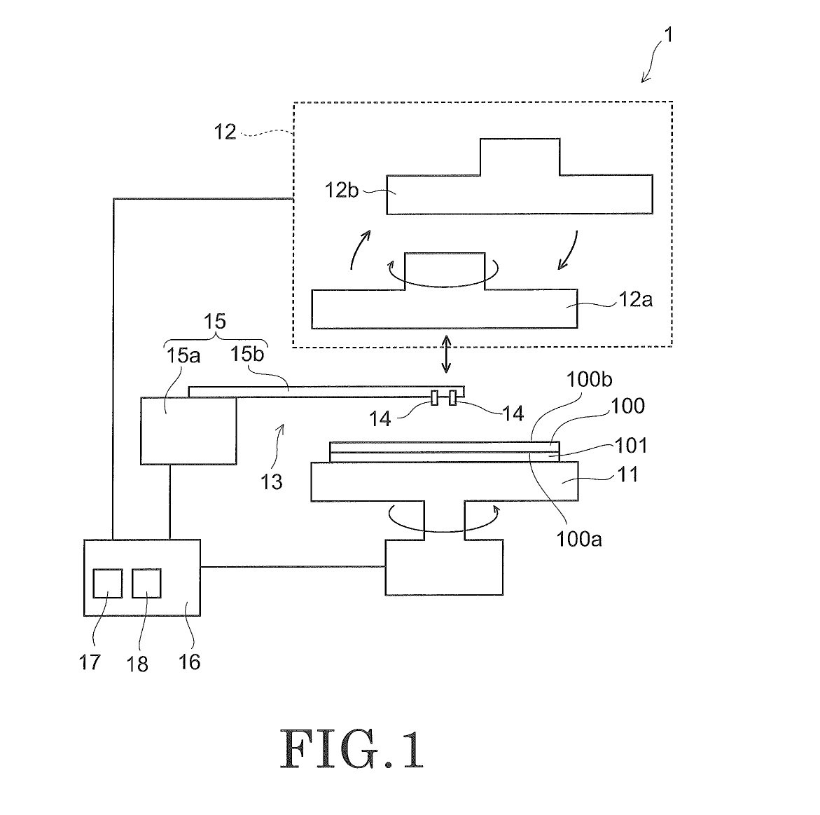

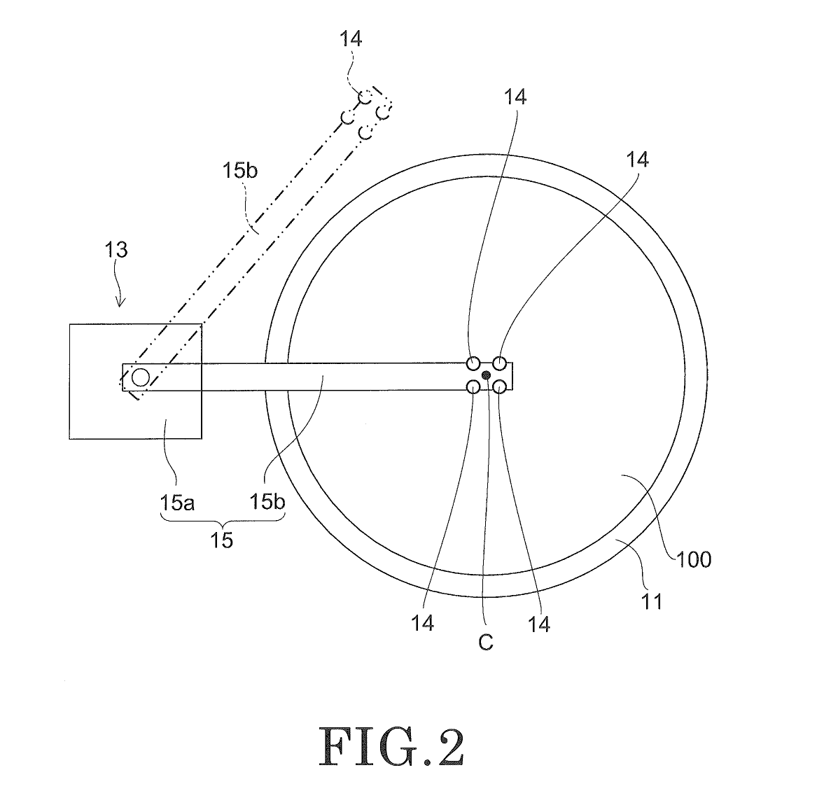

Hereinafter, embodiments will be described with reference to the drawings. A first embodiment will first be described. FIG. 1 is a block diagram showing an apparatus for fabricating a semiconductor device according to the embodiment. FIG. 2 is a plan view schematically showing the apparatus for fabricating a semiconductor device according to the first embodiment.

### First Embodiment

As shown in FIGS. 1 and 2, a fabricating apparatus 1 for fabricating a semiconductor device according to the first embodiment includes a rotation unit 11 to hold a semiconductor wafer (hereinafter, simply referred to as wafer) 100 and also to rotate the wafer 100 with a central axis C of the wafer 100 as a rotation axis. Further, the fabricating apparatus 1 includes a grinding unit 12 to grind the wafer 100 as a thickness reduction unit. The grinding unit 12 includes a rough grinding stone 12a and a fine grinding stone 12b. The grain size of the rough grinding stone 12a is about #300, for example, and the grain size of the fine grinding stone 12b is about #2000, for example. The rotation unit 11 and the grinding unit 12 are configured such that one of the rough grinding stone 12a and the fine grinding stone 12b is selected and the selected stone is pressed against the wafer 100 in a state where the rotation unit 11 holds the wafer 100. Further, the fabricating apparatus 1 includes a transfer unit (not shown) to transfer the wafer 100 within the fabricating apparatus 1. The transfer unit mounts and removes the wafer 100 on/from the rotation unit 11.

Further, the fabricating apparatus 1 includes a measurement unit 13 to measure a sheet resistance of a main surface of the wafer 100. The measurement unit 13 measures a sheet resistance by a Van der Pauw method using the Hall effect. The measurement unit 13 includes a pair of measurement terminals 14 and a moving unit 15 to move those measurement terminals 14 in a radial direction of the semiconductor wafer 100. For example, in the case where a sheet resistance is measured by using the Van der Pauw method, four measurement terminals 14 are provided. The moving unit 15 includes a main body 15a and a bar-like arm 15b. A root portion of the arm 15b is rotatably coupled to the main body 15a. The measurement terminals 14 are attached to a tip portion of the arm 15b. The main body 15a of the moving unit 15 rotates the arm 15b so that the measurement terminals 14 can move along an arc-like trajectory and a position of the wafer 100 in the radial direction can be selected. In addition, the main body 15a can also retract the arm 15b and the measurement terminals 14 from a region immediately above the wafer 100.

Further, the fabricating apparatus 1 includes a control unit 16. The control unit 16 includes a memory section 17 and a decision section 18. The memory section 17 is constituted of a memory such as a random access memory (RAM) and a hard disk and is configured to store a measured value of a sheet resistance that is input from the measurement unit 13. The decision section 18 reads the measured value of the sheet resistance, the measured value being stored in the memory section 17. The decision section 18 decides a target value of thickness to be obtained after the thickness of the wafer 100 is reduced (hereinafter, referred to as “final thickness”), based on the measured value or a representative value of a plurality of measured values. The representative value is an average value, for example. The decision section 18 stores a conversion table in which a correspondence between the sheet resistance and the final thickness is described, or a conversion equation to convert the sheet resistance into the final thickness, for example. The decision section 18 uses the conversion table or the conversion equation, to decide the final thickness based on a measurement result of the sheet resistance. In the embodiment, the sheet resistance is converted into the final thickness such that the final thickness becomes larger as the sheet resistance becomes higher.

The decision section 18 is constituted of a central processing unit (CPU) and a memory, for example.

The control unit 16 controls the rotation unit 11, the moving unit 15, and the measurement terminals 14 to work in cooperation, to measure sheet resistances of the principal surface of the wafer 100 at a plurality of positions. Further, the control unit 16 controls the grinding unit 12 such that the thickness of the wafer 100 approaches the final thickness decided by the decision section 18.

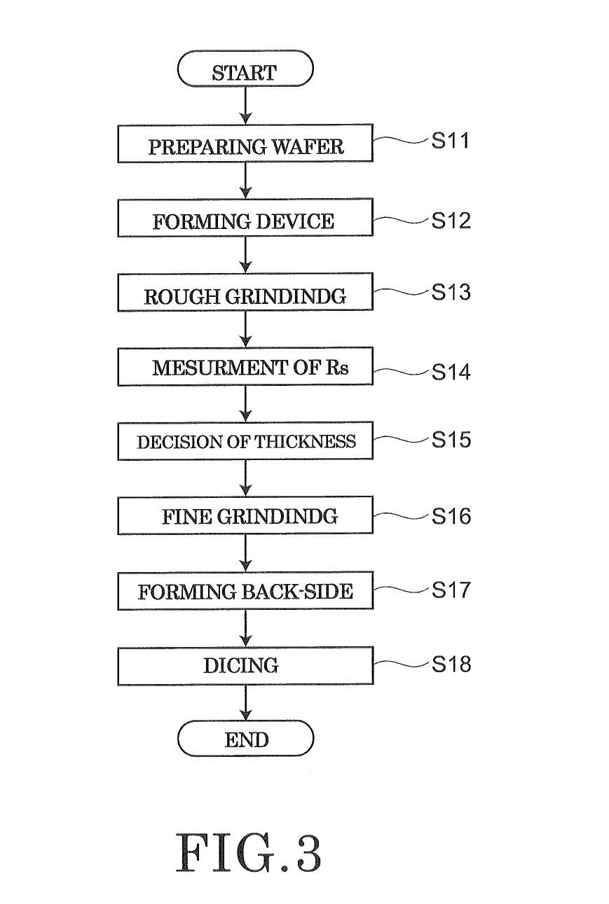

Next, an operation of the apparatus for fabricating a semiconductor device according to the embodiment, that is, a method of fabricating a semiconductor device according to the embodiment will be described. FIG. 3 is a flowchart showing an example of the method of fabricating a semiconductor device according to the embodiment. Hereinafter, the method of fabricating a semiconductor device according to the embodiment will be described with reference to FIGS. 1 to 3.

First, the semiconductor wafer 100 is prepared as shown in Step S11 of FIG. 3. The semiconductor wafer 100 is a silicon wafer, for example, and is a lapped wafer that is not subjected to a diffusion process. Impurities to be donors or acceptors are substantially uniformly introduced into the wafer 100. It should be noted that an impurity concentration varies between the wafers 100 within a certain range. Next, a device structure or a medium-breakdown-voltage MOSFET (high-voltage (HV)-MOS), for example, is formed on a main surface 100a of the wafer 100 as shown in Step S12.

Next, rough grinding is performed on a back surface 100b of the wafer 100 as shown in Step S13. Specifically, a supporting substrate 101 is bonded to the main surface 100a of the wafer 100 via an adhesive agent (not shown) and then set in the fabricating apparatus 1. After that, the transfer unit of the fabricating apparatus 1 mounts the wafer 100 onto the rotation unit 11 with the back surface 100b facing upward. Meanwhile, the grinding unit 12 positions the rough grinding stone 12a in a region immediately above the wafer 100. It should be noted that the wafer 100 may be moved immediately below any grinding stone by fixing a position of the rough grinding stone 12a and that of the fine grinding stone 12b in advance and rotating a rotation stage into which a plurality of rotation units 11 are incorporated.

Next, the rotation unit 11 causes the wafer 100 to rotate with the central axis C of the wafer 100 being a rotation axis. On the other hand, the grinding unit 12 causes the rough grinding stone 12a to rotate in a direction opposite to the rotation direction of the wafer 100. In this state, the grinding unit 12 presses the rough grinding stone 12a against the back surface 100b of the wafer 100. Thus, the back surface 100b of the wafer 100 is subjected to the rough grinding. The rough grinding is ended when the thickness of the wafer 100 reaches a value obtained by adding about 50 μm, for example, to an approximate target value of the thickness at a time of finishing. After the rough grinding is ended, the rough grinding stone 12a is moved upward and retracted in a direction away from the wafer 100.

Next, the measurement unit 13 measures the sheet resistance in-line on a grinding surface of the wafer 100, that is, the back surface 100b as shown in Step S14. Specifically, the main body 15a of the moving unit 15 rotates the arm 15b so that the measurement terminals 14 are positioned in the region immediately above the semiconductor wafer 100. Then, the sheet resistance of the wafer 100 is measured by the Van der Pauw method, for example. At that time, the control unit 16 controls the rotation unit 11 so that a posture angle of the wafer 100 is selected. The control unit 16 also controls the moving unit 15 so that the main body 15a rotates the arm 15b, to select positions of the measurement terminals 14 in the radial direction of the wafer 100. Thus, the measurement terminals 14 are opposed to the back surface 100b of the wafer 100 at any positions, to measure sheet resistances. Then, the control unit 16 controls the rotation unit 11 and the measurement unit 13 to measure sheet resistances at any other positions of the back surface 100b. Hereinafter, the same procedure is repeated.

In such a manner, the control unit 16 causes the rotation unit 11, the moving unit 15, and the measurement terminals 14 to work in cooperation, to measure sheet resistances at a plurality of positions different from one another on the back surface 100b. The measurement unit 13 outputs those measured values to the control unit 16. The control unit 16 causes the memory section 17 to store those measured values. After the measurement, the main body 15a of the moving unit 15 rotates the arm 15b and retracts the measurement terminals 14 from the region immediately above the wafer 100.

Next, the control unit 16 decides a final thickness of the semiconductor wafer 100 based on the measurement results of the sheet resistance as shown in Step S15. Specifically, the decision section 18 of the control unit 16 reads the measured values of the sheet resistance from the memory section 17 and calculates a representative value of the measured values, that is, an average value of the measured values, for example. Then, the decision section 18 refers to the conversion table in which the correspondence between the sheet resistance and the final thickness is described or the conversion equation, to decide a final thickness corresponding to the representative value of the sheet resistance. A correspondence in which the final thickness becomes larger as the sheet resistance becomes higher is described in the conversion table. By the conversion equation, the sheet resistance is converted into the final thickness such that the final thickness becomes larger as the sheet resistance becomes higher.

As will be described later, the sheet resistance of a semiconductor wafer is associated with the impurity concentration of the semiconductor wafer, and as the impurity concentration becomes lower, the sheet resistance becomes higher. Therefore, the sheet resistance of the semiconductor wafer is measured so that the impurity concentration can be evaluated at least relatively. In the embodiment, the final thickness is decided such that the net amount of impurities of the entire semiconductor wafer has a constant value, for example. The net amount of impurities N can be represented by Expression 1 below, where the impurity concentration at each point is represented by n, and a domain of integration is represented by V. The domain of integration V is the entire semiconductor wafer in the embodiment.

N=∫ᵥndv [Expression 1]

Next, fine grinding is performed until the target final thickness described above is obtained as shown in Step S16. Specifically, the grinding unit 12 positions the fine grinding stone 12b in the region immediately above the wafer 100 and presses the fine grinding stone 12b against the back surface 100b of the wafer 100. At that time, the control unit 16 controls the grinding unit 12 to stop grinding when the thickness of the wafer 100 reaches the final thickness decided by the decision section 18. Thus, the thickness of the wafer 100 is reduced such that the final thickness becomes larger as the average value of the sheet resistance becomes higher.

Next, a back-side structure is formed on the back surface 100b of the wafer 100 as shown in Step S17. Impurities are injected by ion implantation and are activated by laser annealing, for example. Further, a back-side electrode is formed. Finally, the supporting substrate 101 and the adhesive agent (not shown) are removed from the wafer 100 and then cleaned. Next, the semiconductor wafer 100 is diced as shown in Step S18. Thus, semiconductor devices are fabricated. It should be noted that a cleaning step, a drying step, and the like may be performed between the steps described above when appropriate.

Next, effects of the embodiment by in operations of the embodiment will be described. In the embodiment, a semiconductor device is fabricated from a semiconductor wafer that is not subjected to a diffusion process. However, the impurity concentration of a semiconductor wafer has variations within a certain range due to the limit of processes. Such variations of the impurity concentration directly lead to variations in characteristics of a complete semiconductor device. For example, when the impurity concentration is relatively low, a depletion layer is easy to expand and the resistance to punch-through is relatively reduced. In contrast, it is assumed that an allowable range of the variations in the impurity concentration is narrowed when a semiconductor wafer is supplied. In this case, however, fabrication costs of the semiconductor wafer increase.

In this regard, in the embodiment, the sheet resistance of the wafer 100 is measured in Step S14 after the rough grinding shown in Step S13 of FIG. 3 and before the fine grinding shown in Step S16 of FIG. 3. As described above, the sheet resistance is a physical amount associated with the impurity concentration of the wafer 100. As the impurity concentration becomes lower, the sheet resistance becomes higher. Therefore, the sheet resistance is measured so that the impurity concentration can be at least relatively evaluated.

The final thickness of the wafer 100 is decided based on the measurement results of the sheet resistance in Step S15. At that time, in the case where the sheet resistance of the wafer 100 is relatively high, that is, the impurity concentration is low, a depletion layer is easy to expand and therefore the final thickness of the wafer 100 is set to be large. Conversely, in the case where the sheet resistance is relatively low, that is, the impurity concentration is high, a depletion layer is difficult to expand and therefore the final thickness of the wafer 100 is set to be small. Thus, even when the impurity concentration varies among a plurality of wafers 100, margins generated when the respective depletion layers expand can be made equal. As a result, the resistance to punch-through can be made uniform.

As a result, even when a normal semiconductor wafer having lower fabrication costs and supply risk than those of a diffusion wafer is used, a semiconductor device with stable characteristics can be fabricated. In particular, the amount of impurities N, which is given by Expression 1 above, is set to be constant among the wafers 100. As a result, a semiconductor device with more stable characteristics can be obtained.

In the embodiment, the sheet resistances are measured at a plurality of positions of the wafer 100, and an average value of the sheet resistances is used to decide a final thickness. Thus, highly reliable measurement results of the sheet resistance can be obtained, and an accurate final thickness can be decided.

In the embodiment, the control unit 16 controls the rotation unit 11 to select a posture angle of the wafer 100. Since the positions of the measurement terminals 14 in the radial direction of the wafer 100 are selected by the control unit 16 controlling the moving unit 15, the measurement terminals 14 can be opposed to the back surface 100b of the wafer 100 at any positions. Thus, the sheet resistances can be measured at any positions of the semiconductor wafer 100.

Furthermore, the sheet resistance is measured by the Van der Pauw method in the embodiment.

Since the Van der Pauw method allows the sheet resistance to be corrected by a transcendental function, a sheet resistance can be measured while absorbing variations in shape of the wafer 100 as a measurement target or variations in roughness and thickness of a grinding surface, for example.

Furthermore, the measurement unit 13 is incorporated into the fabricating apparatus 1 in the first embodiment. The measurement unit 13 measures a sheet resistance in-line. Thus, in the case where a semiconductor wafer is processed one by one, during a period of time in which a wafer is being subjected to fine grinding, a sheet resistance of a subsequent wafer that has been subjected to rough grinding can be measured. Alternatively, during a period of time in which a wafer is being subjected to rough grinding, a sheet resistance of a wafer one wafer after that has been subjected to rough grinding but not yet to fine grinding can be measured. For example, in the case where two or more rotation units 11 are provided in the fabricating apparatus 1 and the rough grinding stone 12a and the fine grinding stone 12b are simultaneously used to perform rough grinding and fine grinding on each of two wafers, the sheet resistance can be measured during a process that requires a longer time out of the rough grinding and the fine grinding. Thus, it is possible to suppress a reduction in throughput of a semiconductor wafer due to the measurement of the sheet resistance.

### Second Embodiment

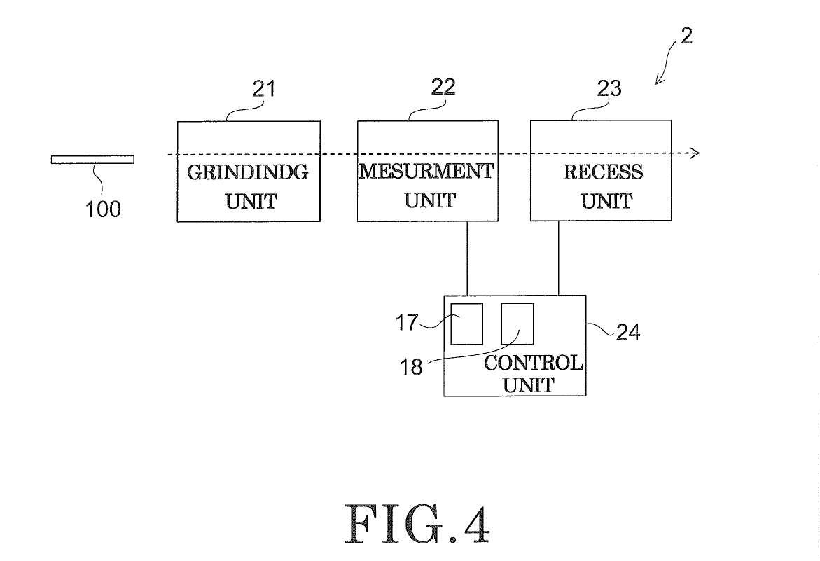

Next, a second embodiment will be described. FIG. 4 is a block diagram showing an apparatus for fabricating a semiconductor device according to the second embodiment. As shown in FIG. 4, an apparatus 2 for fabricating a semiconductor device according to the second embodiment includes a grinding unit 21, a measurement unit 22, a recess unit 23, and a control unit 24. The grinding unit 21 performs rough grinding and fine grinding on a semiconductor wafer 100. The measurement unit 22 measures a sheet resistance of the semiconductor wafer 100 after fine grinding. The recess unit 23 serves as a thickness reduction unit to form a recess in the semiconductor wafer 100 to reduce the thickness of the semiconductor wafer 100. The control unit 24 controls the recess unit 23 based on a measurement result of a sheet resistance by the measurement unit 22.

The grinding unit 21 has a configuration obtained by removing the measurement unit 13 and the control unit 16 from the above-mentioned fabricating apparatus 1 according to the first embodiment (see FIG. 1). The measurement unit 22 has a configuration obtained by adding the rotation unit 11 and the measurement unit 13 shown in FIG. 2. The recess unit 23 is a wet etching apparatus in the second embodiment. The control unit 24 has the same configuration as that of the control unit 16 of the fabricating apparatus 1 and includes a memory section 17 and a decision section 18.

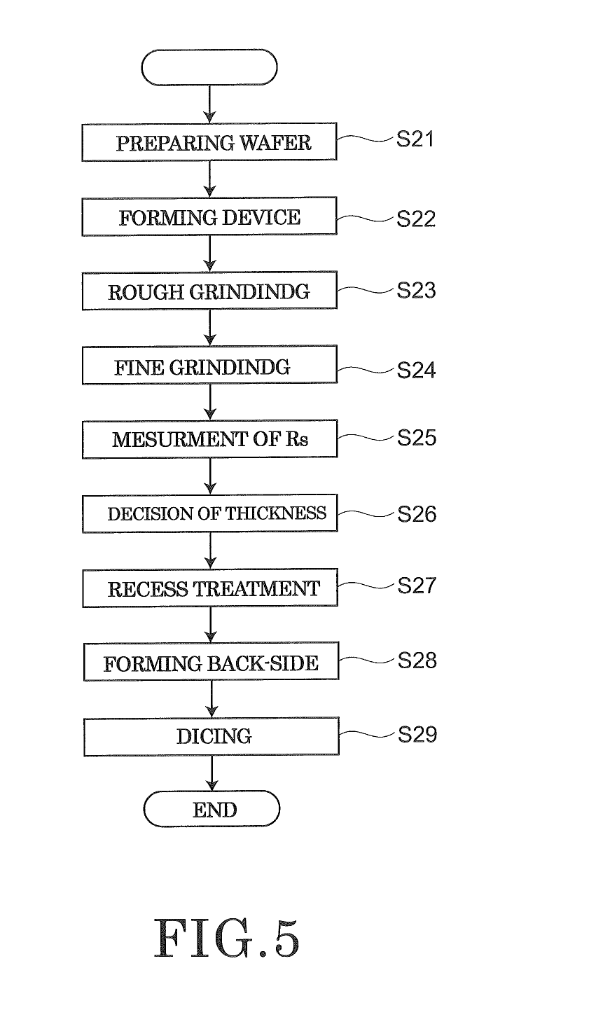

Next, an operation of the fabricating apparatus according to the second embodiment, that is, a method of fabricating a semiconductor device according to the second embodiment will be described. FIG. 5 is a flowchart showing the method of fabricating a semiconductor device according to the second embodiment. Hereinafter, the method of fabricating a semiconductor device according to the second embodiment will be described with reference to FIGS. 4 and 5.

First, the semiconductor wafer 100 is prepared as shown in Step S21 of FIG. 5. The semiconductor wafer 100 is a silicon wafer, for example, and is a wafer that is not subjected to a diffusion process. Next, a device structure or a medium-breakdown-voltage MOSFET (HV-MOS), for example, is formed on a main surface 100a of the wafer 100 as shown in Step S22.

Next, the grinding unit 21 performs rough grinding on a back surface 100b (see FIG. 1) of the wafer 100 as shown in Step S23. At that time, the grain size of a grinding stone to be used is about #300, for example. Next, the grinding unit 21 performs fine grinding on the back surface 100b of the wafer 100 as shown in Step S24. At that time, the grain size of a grinding stone to be used is about #2000, for example.

Next, the measurement unit 22 measures a sheet resistance of the back surface 100b of the wafer 100 as shown in Step S25. A method of measuring a sheet resistance is the same as that of the first embodiment described above. Specifically, the measurement unit 22 measures sheet resistances at a plurality of positions different from one another on the back surface 100b and outputs those measured values to the control unit 24. The control unit 24 stores those measured values in the memory section 17.

Next, the control unit 24 decides a final thickness of the semiconductor wafer 100 based on the measurement results of the sheet resistance as shown in Step S26. A method of deciding a final thickness is the same as that of the first embodiment described above. Next, the recess unit 23 performs recess treatment on the back surface 100b of the wafer 100 so that the thickness of the wafer 100 is reduced to reach the final thickness as shown in Step S27. In the embodiment, wet etching is performed as the recess treatment. At that time, the control unit 24 controls the recess unit 23 so that the thickness of the wafer 100 is reduced to approach the final thickness. For example, the control unit 24 determines an end point of the wet etching.

Next, a back-side structure is formed on the back surface 100b of the wafer 100 as shown in Step S28. Impurities are implanted by ion implantation and are activated by laser annealing, for example. Further, a back-side electrode is formed. Finally, the supporting substrate 101 and the adhesive agent (not shown) are removed from the wafer 100 and then cleaned. Next, the semiconductor wafer 100 is diced as shown in Step S29. Thus, semiconductor devices are fabricated.

According to the second embodiment, in the case where the recess treatment is performed and the back surface 100b of the wafer 100 is formed to be a mirror surface, the sheet resistance is measured after fine grinding and the recess treatment is performed based on a result of the measurement. Thus, as the concentration of impurities contained in the wafer 100 becomes lower, the final thickness of the wafer 100 can be set to be larger as in the first embodiment described above. As a result, even if the impurity concentration of the wafer 100 varies, a semiconductor device with uniform resistance to punch-through can be fabricated. Other configuration, operation, and effects in the embodiment are the same as those in the first embodiment described above.

(First Modification)

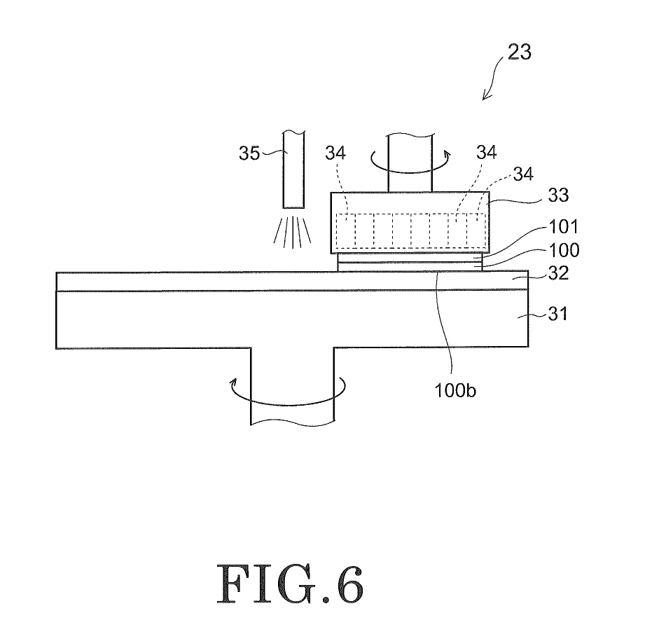

Next, a first modification of the second embodiment will be described. The modification is different from the second embodiment described above in that a recess unit is a chemical mechanical polishing (CMP) apparatus and in that a control unit 24 virtually divides a wafer 100 into a plurality of annular regions coaxially arranged, calculates an average value of sheet resistances for each of the regions, and decides a final thickness for each of the regions. FIG. 6 is a diagram schematically showing a recess unit in the modification.

As shown in FIG. 6, a recess unit 23 in the modification includes a rotation unit at the pad side 31. A polish pad 32 is fixed to a top surface of the rotation unit at the pad side 31. The rotation unit at the pad side 31 rotates the polish pad 32. A rotation unit at the wafer side 33 is provided above the polish pad 32. The rotation unit at the wafer side 33 rotates the semiconductor wafer 100 while holding the semiconductor wafer 100. It should be noted that a rotation axis of the rotation unit at the pad side 31 does not necessarily coincide with a rotation axis of the rotation unit at the wafer side 33. The rotation unit at the wafer side 33 includes a plurality of local press units 34, which are arranged along a direction parallel to a top surface of the polish pad 32. The local press unit 34 is an air bag, for example. Further, the recess unit 23 includes a nozzle 35. The nozzle 35 supplies slurry, pure water, or the like to the top surface of the polish pad 32.

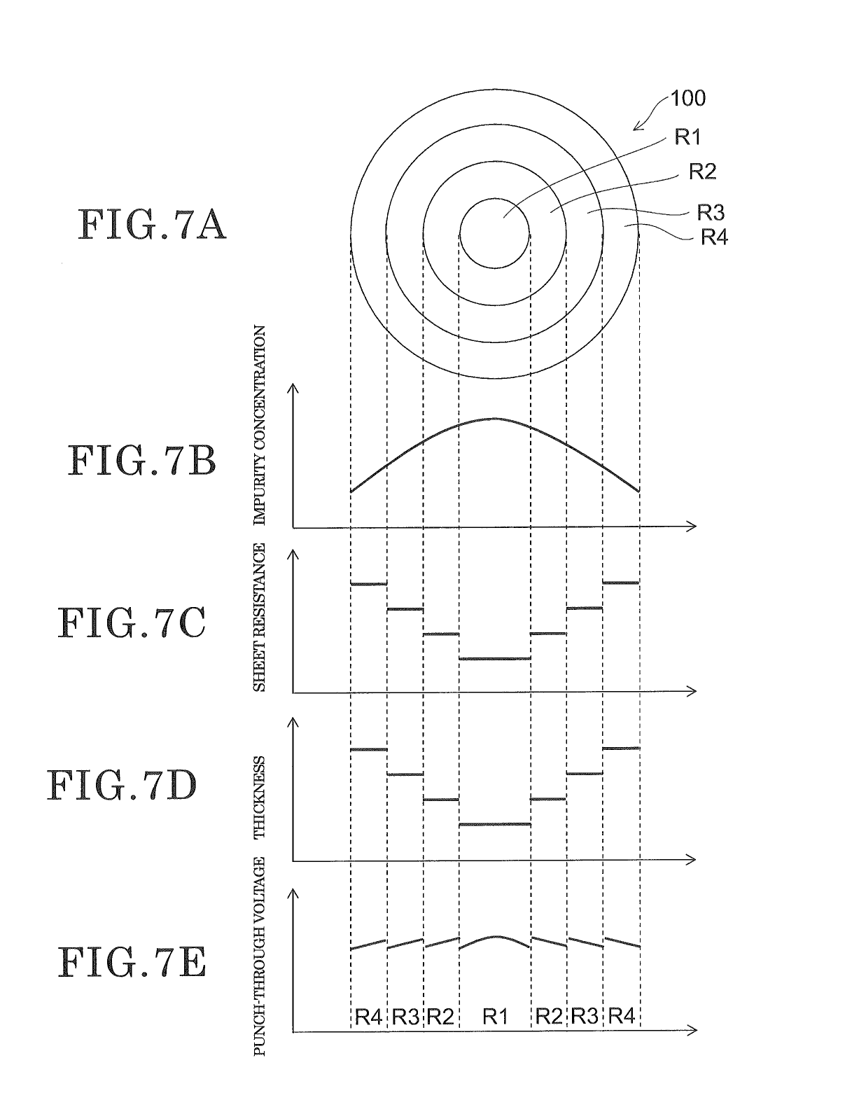

Next, an operation of the apparatus for fabricating a semiconductor device according to the modification, that is, a method of fabricating a semiconductor device according to the modification will be described. FIG. 7A is a plan view showing a semiconductor wafer which is subjected to the recess treatment in the modification. FIGS. 7B to 7E are graphs each showing an example of a distribution of a variable amount in the semiconductor wafer, in which the horizontal axis indicates a position in the semiconductor wafer and the vertical axis indicates variable amounts. FIG. 7B indicates an impurity concentration in the vertical axis. FIG. 7C indicates an average value of sheet resistances in the vertical axis. FIG. 7D indicates a final thickness in the vertical axis. FIG. 7E indicates resistance to punch-through in the vertical axis.

First, the processes in Steps S21 to S24 of FIG. 5 are performed by the same method as that in the second embodiment described above. Specifically, the processes up to the fine grinding for the wafer 100 are performed. Next, the semiconductor wafer 100 is virtually divided into a plurality of regions in the measurement of the sheet resistance shown in Step S25 of FIG. 5. Those regions are decided so as to correspond to the array of the local press units 34. The semiconductor wafer 100 is divided into a plurality of annular regions R1 to R4 which are coaxially arranged in order outwardly from the center of the wafer 100, as shown in FIG. 7A, for example. Then, the measurement unit 22 measures a sheet resistance at a plurality of positions in each of the regions R1 to R4.

Next, in the decision of the final thickness shown in Step S26 of FIG. 5, the control unit 24 calculates an average value of measured values of the sheet resistance in each of the regions R1 to R4. Thus, the distribution of the sheet resistance is obtained. The impurity concentration of the semiconductor wafer is the highest in the region R1, the second highest in the region R2, the third highest in the region R3, and the lowest in the region R4 as shown in FIG. 7B, for example. In this case, the average value of the sheet resistances is the lowest in the region R1, the second lowest in the region R2, the third lowest in the region R3, and the highest in the region R4, as shown in FIG. 7C.

Next, the control unit 24 decides a final thickness for each of the regions based on the average value of the sheet resistances of each of the regions. The final thickness of the region R1, that is, a target value of the thickness of the wafer 100 after the recess treatment is decided based on the average value of the measured values of the sheet resistance, which are measured at the plurality of positions of the region R1, for example. At that time, the final thickness is set to be larger in a region whose sheet resistance is higher. The control unit 24 decides the final thickness of each region such that the amount of impurities is set to be constant per unit area of each region. In this case, the domain of integration V is an entire portion of each region in the thickness direction in Expression 1 above. Thus, in the case where the sheet resistance is distributed as shown in FIG. 7C, for example, the final thickness is the smallest in the region R1, the second smallest in the region R2, the third smallest in the region R3, and the largest in the region R4 as shown in FIG. 7D.

Next, CMP is performed in the recess treatment shown in Step S27 of FIG. 5. Specifically, the semiconductor wafer 100 is mounted onto a bottom surface of the rotation unit at the wafer side 33 as shown in FIG. 6. At that time, a back surface 100b of the wafer 100 is opposed to the polish pad 32. Next, the rotation unit at the pad side 31 is driven to rotate the polish pad 32 and the rotation unit at the wafer side 33 is driven to rotate the wafer 100. The slurry (not shown) is discharged from the nozzle 35 and supplied to the top surface of the polish pad 32. In this state, the rotation unit at the wafer side 33 presses the back surface 100b of the wafer 100 against the polish pad 32. Thus, the back surface 100b is recessed so that the thickness of the wafer 100 is reduced. At that time, the control unit 24 individually controls the local press units 34 of the recess unit 23 and adjusts force to press the wafer 100 against the polish pad 32 for each of the regions R1 to R4. Thus, the distribution of the thickness of the wafer 100 after the recess treatment coincides with the distribution of the final thickness shown in FIG. 7D.

In the semiconductor wafer 100 thus subjected to the recess treatment, the thickness is larger in a region whose sheet resistance is higher, that is, a region whose impurity concentration is lower as shown in FIGS. 7A to 7D. For example, the region R4 has a higher sheet resistance, a lower impurity concentration, and a larger thickness than those of the region R1. Thus, substantially uniform resistance to punch-through is obtained in the regions R1 to R4 as shown in FIG. 7E. A subsequent fabricating method is the same as that of the second embodiment described above.

According to the modification, when a single semiconductor wafer 100 is divided into a plurality of regions and the regions are different from one another in impurity concentration, a final thickness can be decided for each of the regions. Therefore, the resistance to punch-through can be made uniform among the regions.

In other words, in the case where the distribution of the impurity concentration is found in the semiconductor wafer 100, the distribution can be compensated.

Thus, the resistance to punch-through can be made uniform on a chip basis.

Other configuration, operation, and effects in the modification are the same as those in the second embodiment described above.

(Second Modification)

Next, a second modification of the second embodiment will be described. The second modification is different from the first modification described above in that the recess unit 23 shown in FIG. 4 is a plasma etching apparatus. The plasma etching apparatus can locally control an etching strength. Thus, when a single semiconductor wafer 100 is virtually divided into a plurality of regions, a final thickness can be controlled for each of the regions as in the first modification described above. Further, in the modification, the plurality of regions into which the wafer 100 is virtually divided is not limited to the annular regions coaxially arranged. Other configuration, operation, and effects in the modification are the same as those in the first modification described above.

It should be noted that the case where the measurement unit 22 is provided separately from the grinding unit 21 and the recess unit 23 has been described in the second embodiment and the first and the second modifications of the second embodiment that are described above, but the measurement unit 22 is not limited to the above-mentioned case. The measurement unit 22 may be incorporated into the grinding unit 21. In the second embodiment, a sheet resistance is not measured between the rough grinding and the fine grinding. Alternatively, the measurement unit 22 may be provided in an input side of the recess unit 23.

Further, the case where the control unit 24 is provided separately from the grinding unit 21, the measurement unit 22, and the recess unit 23 has been described in the second embodiment and the first and second modifications of the second embodiment which are described above, but the control unit 24 is not limited to the above-mentioned case. The control unit 24 may be incorporated into the grinding unit 21, the measurement unit 22, or the recess unit 23. In the case where the measurement unit 22 and the control unit 24 are incorporated into the grinding unit 21, for example, the configuration of the grinding unit 21 is the same as that of the fabricating apparatus 1 according to the first embodiment described above (see FIG. 1). Alternatively, the control unit 24 may be connected to the measurement unit 22 and the recess unit 23 in a wired or wireless manner and may be connectable via a communication unit such as a local area network (LAN).

### Third Embodiment

Next, a third embodiment will be described. The third embodiment is different from the first and the second embodiments and the modifications of the second embodiment described above in that on-resistance of a vertical MOSFET is made uniform instead of the resistance to punch-through. As described above, the fact which a sheet resistance is relatively high at a certain position indicates that an impurity concentration at the position is relatively low. When the impurity concentration is low, a resistivity at the position in a thickness direction is high. Assuming that the thickness of a wafer is constant, on-resistance between a source and a drain of the vertical MOSFET is high. For that reason, the on-resistance of the vertical MOSFET varies due to variations in impurity concentration.

In this regard, in the third embodiment, in the case where the sheet resistance is relatively high, the thickness of the wafer is set to be relatively small. Thus, a resistance value of the semiconductor wafer in the thickness direction becomes constant, and the on-resistance between the source and the drain of the vertical MOSFET becomes uniform. A method of measuring a sheet resistance and a method of deciding a final thickness in the third embodiment are the same as those in the first embodiment described above. However, a conversion table or a conversion equation of the third embodiment is different from that stored in the decision section 18 of the first embodiment described above (see FIG. 1).

According to the third embodiment, the on-resistance of the vertical MOSFET can be made uniform. In contrast, in the case where the resistance to punch-through needs to be made uniform, the first and the second embodiments and the modifications of the second embodiment only need to be performed. In such a manner, the embodiments can be selected in accordance with the characteristics needed to be made uniform. Other configuration, operation, and effects in the embodiment described above are the same as those in the first embodiment. Further, the third embodiment may be combined with the second embodiment or each of the modifications of the second embodiment described above.

It should be noted that the case where the average value is used as the representative value of the measured values of the sheet resistance has been described in each of the embodiments described above, but the representative value is not limited to the average value. The representative value may be an index capable of accurately representing a sheet resistance for each wafer or region or may be any statistic. Further, the measured value of the sheet resistance may be used without change.

Further, the case where the sheet resistance is measured by the Van der Pauw method has been described in each of the embodiments described above, but the measurement method is not limited to the Van der Pauw method. For example, an alternating-current magnetic field may be applied to one surface of a semiconductor wafer and measured on the other surface of the semiconductor wafer so that a loss due to an eddy current generated in the semiconductor wafer is calculated and a sheet resistance is obtained based on the loss. Thus, a sheet resistance can be measured in a non contact manner with respect to a semiconductor wafer.

Further, the case where the sheet resistance is adopted as a physical amount associated with the impurity concentration has been described in each of the embodiments described above. However, the physical amount is not limited to the sheet resistance, and any physical amount may be used as long as it corresponds to the impurity concentration with high reproducibility. For example, the impurity concentration itself may be measured by a non contact method.

Furthermore, the case where the medium-breakdown-voltage power semiconductor device is fabricated as a semiconductor device has been described in each of the embodiments described above. However, the semiconductor device is not limited to the medium-breakdown-voltage power semiconductor device. The embodiments described above may be suitably applicable to a process of reducing the thickness of a semiconductor wafer in a fabrication process for a discrete device or the like.

According to the embodiments described hereinabove, it is possible to achieve a method for fabricating a semiconductor device, a semiconductor wafer, and an apparatus for fabricating a semiconductor device, the semiconductor device having stable characteristics.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A method of fabricating a semiconductor device, comprising:
measuring a physical amount related to an impurity concentration of a semiconductor wafer having a first thickness;
deciding a second thickness of the semiconductor wafer based on a measurement value of the physical amount, the second thickness being thinner than the first thickness; and
reducing the first thickness of the semiconductor wafer to approximately the same thickness as the second thickness.

2. The method of claim 1, wherein
in the deciding, the second thickness is set to be thicker as the impurity concentration is lower.

3. The method of claim 1, wherein
in the deciding, the second thickness is set to be thinner as the impurity concentration is lower.

4. The method of claim 1, wherein
the physical amount is a sheet resistance of the semiconductor wafer.

5. The method of claim 1, wherein
in the measuring, the physical amount is measured at each of a plurality of positions on a main surface of the semiconductor wafer, and in the deciding, the second thickness of the wafer is decided on a basis of a representative value of the physical amount in each of the positions.

6. The method of claim 1, wherein
in the deciding, the second thickness is decided such that the impurity concentration of the semiconductor wafer is set to be constant.

7. The method of claim 1, wherein
in the measuring, each of the physical amounts is measured at each of the plurality of the positions on the main surface of the semiconductor wafer, and in the deciding, the second thickness of the wafer is decided on a basis of a measurement value at each position.

8. The method of claim 7, wherein
each position is set to be in each of a plurality of annular regions coaxially.

9. The method of claim 8, wherein
in the deciding, the second thickness is decided such that the impurity concentration of each annular region is set to be constant.

10. A semiconductor wafer, comprising:
a first region having a first impurity concentration, a first sheet resistance and a first thickness; and
a second region having a second impurity concentration, a second sheet resistance and a second thickness;
wherein both the first region and the second region are satisfied with at least one relation of the first impurity concentration being lower than the second impurity concentration and the first thickness being thicker than the second thickness, the first sheet resistance being higher than the second sheet resistance and the first thickness being thicker than the second thickness, the first impurity concentration being lower than the second impurity concentration and the first thickness being thinner than the second thickness, and the first sheet resistance being higher than the second sheet resistance and the first thickness being thinner than the second thickness.

11. The semiconductor wafer of claim 10, comprising:
each of the first region and the second region is set to be in each of a plurality of annular regions coaxially.

12. Apparatus for fabricating a semiconductor device, comprising:
a measurement unit measuring a physical amount related to an impurity concentration of a semiconductor wafer having a first thickness;
a decision unit deciding a second thickness of the semiconductor wafer based on a measurement value of the physical amount, the second thickness being thinner than the first thickness; and
a control unit controlling the first thickness to approximately the same thickness as the second thickness.

13. Apparatus of claim 12, wherein
the control unit controls such that the second thickness is set to be thicker as the impurity concentration is lower.

14. Apparatus of claim 12, wherein
the control unit controls such that the second thickness is set to be thinner as the impurity concentration is lower.

15. Apparatus of claim 12, wherein
the physical amount is a sheet resistance of the semiconductor wafer.

16. Apparatus of claim 12, further comprising;
a rotation unit rotating the semiconductor wafer
wherein the measurement unit includes a measurement terminal to measure the physical amount and a moving unit to move the measurement terminal in a radial direction of the semiconductor wafer, and the control unit causes the rotation unit, the measurement unit and the moving unit to work in cooperation to measure the physical amounts at a plurality of positions on a main surface
